(19) United States
(12) Patent Application Publication
(10) Pub. No.: US 2026/0303135 A1
(43) Pub. Date: Oct. 1, 2026

(54) Methods and Apparatuses for Amplitude-Only Out-of-Band DPD

(71) Applicant: Telefonaktiebolaget LM Ericsson (publ), Stockholm (SE)

(72) Inventor: Mohamed Hamid, Malmö (SE)

(21) Appl. No.: 19/478,709

(22) PCT Filed: May 31, 2023
(86) PCT No.: PCT/EP2023/064610

§ 371 Date: Oct. 24, 2025

(51) Int. Cl. H04B 1/04; H03F 1/32; H03F 3/24; H04B 1/00

(52) U.S. Cl. CPC H04B 1/0475; H03F 1/3241; H03F 3/245; H04B 1/005; H03F 2200/451; H04B 2001/0408

(57) ABSTRACT

A method of performing digital predistortion, DPD, on a first signal, x, to generate a pre-distorted signal, x_{pre-d} for driving a power amplifier, wherein the first signal comprises an in-band component, x_{iB}, consisting of one or more first frequency bands and an out-of-band component, x_{OoB} consisting of one or more second frequency bands, the method comprising: obtaining (102) amplitudes, |x|, of the first signal; performing (104) DPD by applying a DPD model to the amplitudes of the first signal to obtain amplitudes of a second signal, |ûₗ|; and replacing (106) the out-of-band component, x_{OoB}, of the first signal with a third signal, z, derived from the amplitudes of the second signal, |ûₗ|, to obtain the pre-distorted signal, wherein the third signal, z, consisting of the one or more second frequency bands.

### TECHNICAL FIELD

Embodiments described herein relate to methods and apparatuses for performing out-of-band digital predistortion.

### BACKGROUND

A power amplifier (PA) is a nonlinear device that boosts the power of a radio frequency (RF) signal and feeds it to one or more radiating antenna. To provide satisfactory efficiency, PAs are usually driven with significant input power. However, the nonlinearity of the PA increases with increased input power.

The nonlinearity of PAs results in a degradation of the quality of the emitted signal, which hinders not only the achievable modulation schemes, but also creates unwanted emissions within the adjacent channels and outside the operating band due to spectral regrowth. These unwanted emissions are referred to as out-of-band emissions (OoBE). The characteristics of PAs that cause unwanted emissions are severely regulated by Third Generation Partnership Project (3GPP) specifications (see for example, ETSI, “3GPP TS 38.104 version 15.14.0 Release 15,” 2021). 3GPP in-band linearity requirements relate to allowed error vector magnitude (EVM), and 3GPP OoBE linearity requirements relate to spectral mask and adjacent channel leakage ratio (ACLR).

A widely adopted approach for mitigating the effects of a PA's nonlinearity is to pre-process the signal in the digital domain by means of a digital pre-distortion (DPD) process. This approach, which has countless variants, has its foundations in the idea of compensating for the nonlinear behaviour by determining and applying an inverse nonlinear transformation to the PA input signal. A DPD module may be considered a functional block part of the digital front end (DFE) which pre-processes (e.g., pre-distorts) input signals such that the cascade of the DPD module and PA has a net effect that is as linear as possible.

DPD may be used to linearise both single-band signals and multiband signals. A single DPD module may linearise all signal bands in a multiband signal. Alternatively, to reduce bandwidth requirements, separate DPD (S-DPD) modules may be used to perform DPD for each signal band separately.

DPD may also be used to linearise both in-band and out-of-band (OoB) signal distortion. DPD may be used to compensate for both in-band and out-of-band distortion simultaneously by suppressing amplitude-to-amplitude distortion (AM-AM) and amplitude to phase distortion (AM-PM).

In some cases, either the in-band distortion requires more suppression than the OoBE, or the OoBE requires more suppression than the in-band distortion. In such scenarios, a DPD module may be designed based on the most stringent requirements (i.e., the signal is suppressed based on the maximum required suppression). However, this can lead to an unnecessarily complex DPD module or a solution that fails to fulfil either requirement. In particular, full band (FB) linearization requires high sampling rates (to enable wideband DPD) which may not be needed if narrower portions of spectrum impose more stringent OoBE requirements than others.

Some efforts have been made to address this problem of performing DPD when either the in-band distortion or OoBE requires more suppression than the other.

In X. Xia et al., “An Out-of-Band Digital Predistortion Scheme and Its Verification for Power Amplifiers with Strong Nonlinearity” 2021 IEEE MTT-S International Microwave Symposium (IMS), 2021, pp. 614-617, a technique for filtering the error of iterative learning control (ILC) architecture to find a DPD module that suppresses the OoB more than the in-band by concentrating the energy held by each basis in the out of band region. The technique applies a high pass FIR filter on the error signal after first iteration of ILC. Therefore, the rest of the iterations consider only OoB distortion suppression. This solution helps in finding the bases needed to suppress OoBE, but the modelling complexity is still high because a large over sampling ratio (OSR) is needed to have a sufficient bandwidth to cover both in-band and out of band high-order distortions.

WO2022262991 makes use of S-DPD modules, which leaves some intermodulation (IM) distortions for analogue filtering and therefore requires additional hardware. Otherwise, a S-DPD module is added to address fewer portions within inter-band spectrum to avoid interfering with uplink (UL) signals. However, the solution proposed therein uses the conventional approach to DPD of correcting for both AM/AM and AM/PM, which comprises high DPD complexity.

Per Landin, “Digital Baseband Modeling and Correction of Radio Frequency Power Amplifiers” PhD thesis, KTH Royal Institute of Technology, 2012 (section 33 pages 31-35) introduces use of a frequency weighting function to minimize a more relevant cost function than the frequency neutral cost function. For example, this approach could be used to suppress the out-of-band distortion more than the in-band distortion. However, this solution still requires running the whole DPD module at a rate that covers the entire frequency range to be linearized. Moreover, it involves a convolution operation in the frequency domain which comes with an added computational complexity and hence higher power consumption.

Therefore, DPD that mitigates only the in-band or the out-of-band signal is needed.

### SUMMARY

Certain aspects of the present disclosure and their embodiments may provide solutions to these or other challenges.

According to some embodiments there is provided a method of performing digital predistortion, DPD, on a first signal, x, to generate a pre-distorted signal, x_{pre-d}, for driving a power amplifier. The first signal comprises an in-band component, x_{iB}, consisting of one or more first frequency bands and an out-of-band component, x_{OoB}, consisting of one or more second frequency bands. The method comprises: obtaining amplitudes, |x|, of the first signal; performing DPD by applying a DPD model to the amplitudes of the first signal to obtain amplitudes of a second signal, |ûₗ|; and replacing the out-of-band component, x_{OoB}, of the first signal with a third signal, z, derived from the amplitudes of the second signal, |uₗ|, to obtain the pre-distorted signal, x_{pre-d}. The third signal, z, consists of the one or more second frequency bands.

According to some embodiments, there is provided a digital predistortion, DPD, system configured to perform DPD on a first signal, x, to generate a pre-distorted signal, x_{pre-d}, for driving a power amplifier. The first signal comprises an in-band component, x_{iB}, consisting of one or more first frequency bands and an out-of-band component, x_{OoB}, consisting of one or more second frequency bands. The DPD system comprises processing circuitry configured to cause the DPD system to: obtain amplitudes, |x|, of the first signal; perform DPD by applying a DPD model to the amplitudes of the first signal to obtain amplitudes of a second signal, |ûₗ|; and replace the out-of-band component, x_{OoB}, of the first signal with a third signal, z, derived from the amplitudes of the second signal, |ûₗ|, to obtain the pre-distorted signal, x_{pre-d}. The third signal, z, consists of the one or more second frequency bands.

According to some embodiments, there is provided a digital predistortion, DPD, system configured to perform DPD on a first signal, x, to generate a pre-distorted signal, x_{pre-d}, for driving a power amplifier. The first signal comprises an in-band component, x_{iB}, consisting of one or more first frequency bands and an out-of-band component, x_{OoB}, consisting of one or more second frequency bands. The DPD system comprises: a first amplitude module (233) configured to obtain amplitudes, |x|, of the first signal; a DPD module (234) configured to perform DPD by applying a DPD model to the amplitudes of the first signal to obtain amplitudes of a second signal, |ûₗ|; and a replacement module (260) configured to replace the out-of-band component, x_{OoB}, of the first signal with a third signal, z, derived from the amplitudes of the second signal, |ûₗ|, to obtain the pre-distorted signal, x_{pre-d}. The third signal, z, consists of the one or more second frequency bands.

It is identified that the suppression of OoB energy only requires amplitude distortion (AM/AM) correction, and that phase distortion (AM/PM) correction is not needed. Therefore, the proposed solution splits AM/AM and AM/PM distortions and considers AM/AM only.

Thus, the DPD techniques described herein reduce OoBE by correcting only for amplitude (AM/AM) distortion, and thereby utilise the fact that PAs are amplitude driven devices. Aspects and examples of the present disclosure thus overcome some of the limitations of X. Xia et al., “An Out-of-Band Digital Predistortion Scheme and Its Verification for Power Amplifiers with Strong Nonlinearity” 2021 IEEE MTT-S International Microwave Symposium (IMS), 2021, pp. 614-617; WO2022262991; and Per Landin, “Digital Baseband Modeling and Correction of Radio Frequency Power Amplifiers” PhD thesis, KTH Royal Institute of Technology, 2012 (section 33 pages 31-35).

The techniques described herein also allow the use of different basis functions for the OoB signal than those used for the in-band signal. Thus, different bases can be selected for in-band and out-of-band suppression based on different requirements. Furthermore, OoBE in different OoB regions can be suppressed differently using different model structures.

The techniques described herein further benefit from reduced computational complexity, since characterising only the amplitude distortion reduces the dimensionality of the problem by a halve compared to amplitude and phase characterisation. The present techniques enable the OoBE to be suppressed by a different amount to the in-band distortion as needed, which prevents complexity over-dimensioning.

### BRIEF DESCRIPTION OF THE DRAWINGS

For a better understanding of the embodiments of the present disclosure, and to show how they may be put into effect, reference will now be made, by way of example only, to the accompanying drawings, in which:

FIG. 1 is a flow chart illustrating a method according to some embodiments;

FIG. 2 illustrates a DPD system according to some embodiments;

FIG. 3 illustrates down-sampling according to some embodiments;

FIG. 4 illustrates an advanced antenna system in accordance with some embodiments;

FIG. 5 is a block diagram in accordance with some embodiments; and

FIG. 6 is a block diagram in accordance with some embodiments.

### DETAILED DESCRIPTION

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

The following sets forth specific details, such as particular embodiments or examples for purposes of explanation and not limitation. It will be appreciated by one skilled in the art that other examples may be employed apart from these specific details. In some instances, detailed descriptions of well-known methods, nodes, interfaces, circuits, and devices are omitted so as not obscure the description with unnecessary detail. Those skilled in the art will appreciate that the functions described may be implemented in one or more nodes using hardware circuitry (e.g., analog and/or discrete logic gates interconnected to perform a specialized function, ASICs, PLAs, etc.) and/or using software programs and data in conjunction with one or more digital microprocessors or general-purpose computers. Nodes that communicate using the air interface also have suitable radio communications circuitry. Moreover, where appropriate the technology can additionally be considered to be embodied entirely within any form of computer-readable memory, such as solid-state memory, magnetic disk, or optical disk containing an appropriate set of computer instructions that would cause a processor to carry out the techniques described herein.

Hardware implementation may include or encompass, without limitation, digital signal processor (DSP) hardware, a reduced instruction set processor, hardware (e.g., digital or analogue) circuitry including but not limited to application specific integrated circuit(s) (ASIC) and/or field programmable gate array(s) (FPGA(s)), and (where appropriate) state machines capable of performing such functions.

As described above, PA non-linearities may create an OoBE at its output. In order to characterise and mitigate this OoBE, a predistorter (e.g. a DPD module) may need to receive an input signal comprising the bandwidth that the OoBE occupies. Therefore, a baseband time domain information signal that is composed of modulated subcarriers, x_{info}(n), may be up sampled to generate the signal x(n), which is the PA input signal. The PA output signal can then be divided into in-band and out-of-band components. While the in-band signal contains the information to be transmitted bearing a distortion added to it, the out-of-band signal is distortion only, since the out-of-band component is generated by PA non-linearity within a part of the spectrum in which no information signal is placed. In-band and out of band components of the PA output signal can be expressed as:

$$y ( n ) = {y}_{info} ( n ) + {y}^{ob} ( n ) \qquad ( 1 )$$

where y(n) is the entire output, y_{info}(n) is the in-band information output, and y^{ob}(n) is the out-of-band distortion. The out-of-band distortion may comprise a plurality of out-of-band components. Since all signals are time dependent, for simplicity, the time index, n, is dropped in the following discussion.

To mitigate PA non-linear distortion, signals are pre-distorted digitally using DPD before they are converted to analogue signals and thereafter fed to the PA. Mathematically, the time domain DPD output is found as follows:

$${F}_{DPD} ← Minimize {‖ {y}_{a} - {F}_{PA} ( {F}_{DPD} ( \vert x \vert ) ) ‖}^{2} \qquad ( 2 )$$

where F_{DPD}(⋅) is the model of a pre-distorter, F_{PA}(⋅) is the response of the PA, y_{d} is the desired output signal which is a linearly amplified input signal x, and ∥⋅∥² denotes norm squared. The signal y_{d} may be considered desired as it comprises an appropriate representation of the data that the system wishes to convey, with minimal noise or interference.

Time domain DPD handles both in-band and out-of-band distortions and does not differentiate them. However, in several cases OoBE needs to be suppressed further than what a conventional time domain DPD can attain.

For example, when linearising multiband signals using separate DPD (S-DPD) for each band, intra-band distortion is linearised but most of the inter-band distortion is left for analogue filtering, as described in WO2022262991. Such inter-band distortion may fall within UL band generating self-interference and saturate a receiver low-noise amplifier (LNA). Given the imbalance between downlink (DL) and UL power levels, in most cases, this self-interference needs to be suppressed, more than what can be achieved with analogue filtering, using dedicated S-DPD targeting intermodulation distortions falling within those UL bands.

OoB-only suppression may also be required in a system that has an in-band distortion that causes a permittable EVM in the case of low modulation order, but in which the OoBE suppression is still needed to fulfil the legal requirements determined by ACLR and spectral masks.

Particular embodiments are now described more fully with reference to the accompanying drawings. Other embodiments, however, are contained within the scope of the subject matter disclosed herein. The disclosed subject matter should not be construed as limited to only the embodiments set forth herein; rather, these embodiments are provided by way of example to convey the scope of the subject matter to those skilled in the art.

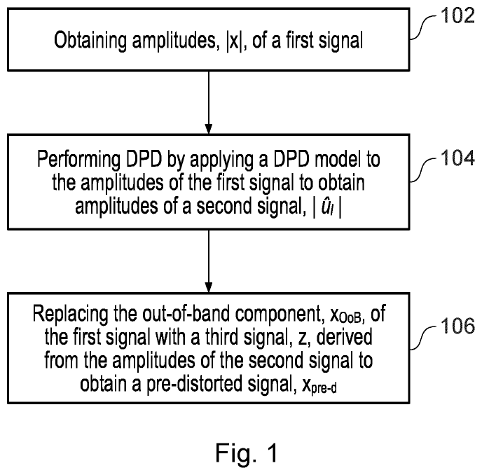

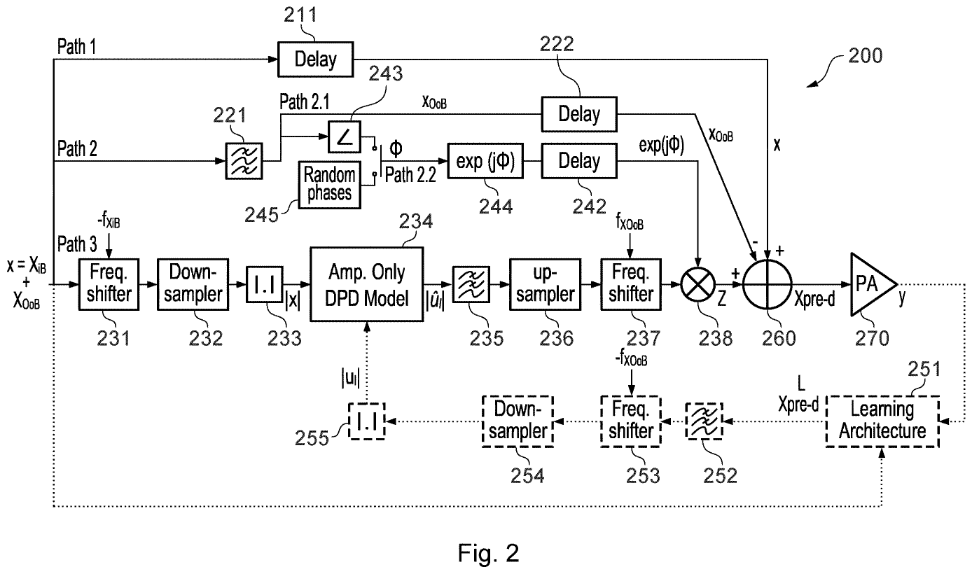

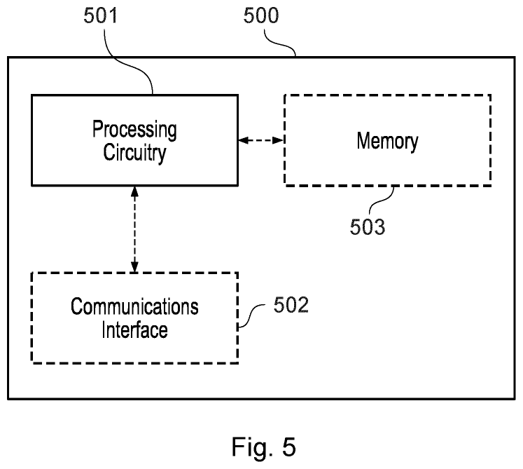

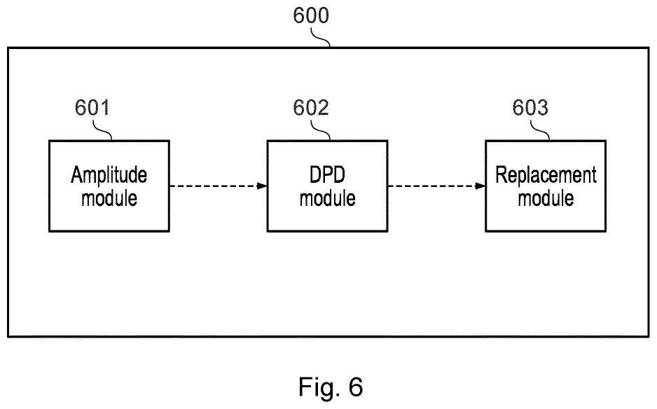

FIG. 1 illustrates a method of performing digital predistortion, DPD, according to some embodiments of the present disclosure. The method may, for example, be performed by the DPD system 200 illustrated in FIG. 2, the apparatus 500 described with reference to FIG. 5, and/or the apparatus 600 described with reference to FIG. 6. The method may be implemented, for example, in a network node, e.g., a base station, in a communication network. Digital predistortion of a signal according to the method of FIG. 1 may be performed by the digital front end (DFE) of a base station prior to amplification and transmission of the signal. The base station may comprise distributed components and/or may be implemented as a cloud-RAN based system.

The DPD is performed on a first signal, x, to generate a pre-distorted signal, x_{pre-d}, for driving a power amplifier. The first signal comprises an in-band component, x_{iB}, consisting of one or more first frequency bands and an out-of-band component, x_{OoB}, consisting of one or more second frequency bands. The one or more first frequency bands may be used to transmit data. The one or more second frequency bands are referred to herein as the OoB region of interest, l, where l can take any integer from 1 to L, and L is the number of different OoB components that make up the region of interest. It will be appreciated that the first signal may comprise further out-of-band component(s) consisting of frequency bands that are outside the OB region of interest.

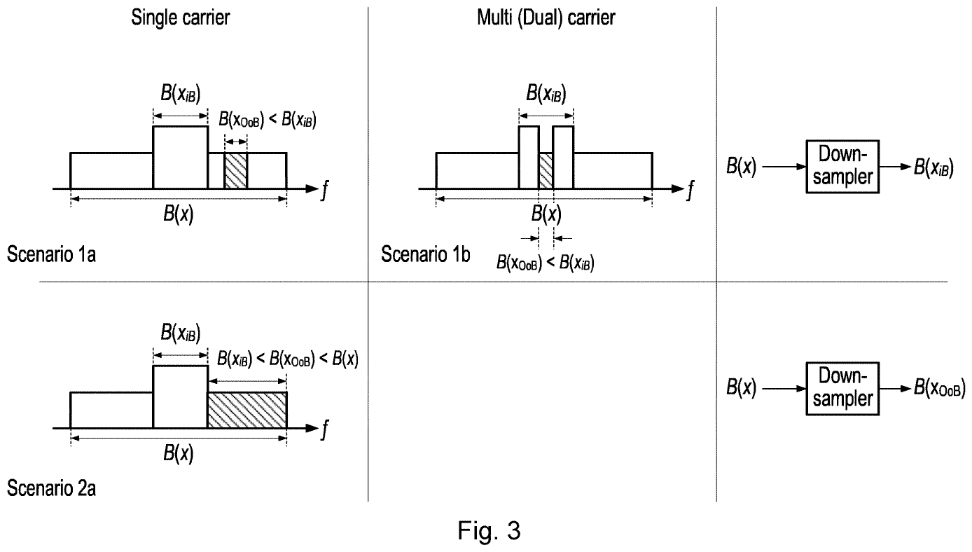

The first signal, x, differs depending on the use case. For example, the first signal, x, may be an output of a previous digital predistortion. Thus, in the case of two-stage frequency selective DPD where the first stage is conventional DPD and the second stage suppresses the OoB energy, xϵ [symbol] ^{N×1} represents the output of the first DPD stage. On the other hand, in a multiband scenario, xϵ [symbol] ^{N×Q} may represent the input to all Q bands. Thus, the out-of-band component, x_{OoB}, of the first signal may comprise inter-band frequencies of the multiband signal. For the ease of explanation, the general notation, x, is used throughout this disclosure for the input signal (the first signal). Furthermore, the out-of-band component, x_{OoB}, may comprise inter-band regions and/or inter-carrier regions in a multi-carrier scenario (for example as illustrated in scenario 1b of FIG. 3 described below). The out-of-band component, x_{OoB}, of the first signal may comprise unused subcarrier frequencies of a single-carrier signal.

As PAs are amplitude driven devices, the amplitude and phase responses of the PA may be split and both may be modelled as a function of the PA input signal amplitude, |x|, (for example, see M. Isaksson, D. Wisell and D. Ronnow, “Wide-band dynamic modeling of power amplifiers using radial-basis function neural networks,” in IEEE Transactions on Microwave Theory and Techniques, vol. 53, no. 11, pp. 3422-3428 November 2005, Section II).

The energy emitted by a PA depends solely on the amplitudes of the amplified signal. Since the objective of out-of-band DPD is to minimize OoB emitted energy, only the amplitude of the PA response in the out-of-band needs to be considered. Therefore, for OoB distortion, the phase response may be eliminated (or ignored) and the out-of-band DPD may be estimated as an amplitude response only.

As only the amplitudes of the out-of-band response of the PA need to be considered, it will be appreciated that this information may be modelled on the basis of the amplitudes of the input signal.

Thus, in step 102, the method of FIG. 1 comprises obtaining amplitudes, |x|, of the first signal. Eliminating the phase response in this manner saves computational resources by reducing input dimensionality by a half.

In some embodiments, prior to obtaining the amplitudes of the first signal, the method of FIG. 1 further comprises performing one or more first processing steps on the first signal. For example, the one or more first processing steps may be any one or more of the first processing steps described with reference to FIG. 2.

The one or more first processing steps may comprise down sampling the first signal. This down-sampling of the first signal is described in more detail with reference to FIGS. 2 and 3 of the present disclosure.

Down sampling the input signal effectively means that the OoB DPD is run at a reduced sampling rate which means that the DPD can be performed using less energy and complexity.

In step 104, the method of FIG. 1 further comprises performing DPD by applying a DPD model to the amplitudes of the first signal to obtain amplitudes of a second signal, |ûₗ|.

The DPD model may be amplitude-only.

For example, the DPD model may be represented as:

$${F}_{DPD}^{ob} ← Minimize {‖ {y}_{d}^{ob} - {F}_{PA}^{ob} ( {F}_{DPD}^{ob} ( x ) ) ‖}^{2} \qquad ( 3 )$$

where

$${F}_{DPD}^{ob}$$

is the DPD model designed to handle out-of-band distortion within the out-of-band region of interest;

$${y}_{d}^{ob}$$

is the desired output within the out-of-band region of interest;

$${F}_{PA}^{ob}$$

denotes the out-of-band distortion due to the PA; and x is the first signal (i.e., the input signal). It will be appreciated that in many cases the

$${y}_{d}^{ob}$$

may be zero.

The desired DPD output signal amplitude within the OoB region of interest, l, may be modelled as

$$\vert {\hat{u}}_{l} \vert = H ( \vert x \vert ) {w}_{l}^{amp} \qquad ( 4 )$$

Where H(|x|) is an amplitude only regression matrix containing the DPD model basis functions;

$${w}_{l}^{amp}$$

is the amplitude-only model coefficients vector, and x is again the first signal. In other words, the DPD model models the desired DPD output signal amplitude within the OoB region of interest based on the amplitudes of the first signal. In this case the desired DPD output signal amplitude may be the DPD output signal amplitude that results in the output of the amplitude in the OoB region of interest being

$${y}_{d}^{ob}$$

(e.g. zero).

The DPD model may be learnt using a learning architecture such as indirect learning architecture (ILA), direct learning architecture (DLA), or iterative leaning control (ILC). It will be appreciated that the techniques described herein may be performed using a DPD model obtained by any learning architecture. Advantageously, the training of the DPD model may be performed offline, e.g., prior to deployment of the DPD system or at sparse intervals, for examples when there may be some expected variation in the power amplifier that may change its non-linear response. Thus, the computational complexity of the digital predistortion performed in step 104 of FIG. 1 is greatly reduced since the DPD model has effectively been pre-determined. The DPD model may be updated at any time, e.g., according to a periodic update and/or in response to changes in the power amplifier. However, the DPD model does not need to be continuously trained. In some embodiments, the DPD model may be a “white box” model in which the model is not learnt but is instead built using fetched parameters, e.g., temperature. A process of training/learning the DPD model according to some embodiments will be described in more detail with reference to FIG. 2.

Although the amplitude-only OoB DPD is model-structure agnostic, two example sets of basis functions which may form the regression matrix H(|x|) are shown below.

### 1. Generalized Memory Polynomial (GMP) Model:

$${h}_{n} ( \vert x \vert ) = {\sum }_{{m}_{1} = 0}^{{M}_{1}} {\sum }_{{m}_{2 = - {m}_{1}}}^{{M}_{2}} {\sum }_{p = 0}^{( P - 1 ) / 2} \vert x ( n - {m}_{1} ) \vert {\vert x ( n - {m}_{1} - {m}_{2} ) \vert}^{2 p} \qquad ( 5 )$$

Where hₙ(|x|) is the n-th row of H(|x|), n is the time domain sample index, M₁, M₂ are memory depths of the GMP model, and P is the non-linearity order.

### 2. Gaussian Radial Basis Functions (RBF)

The n-th row of H(|x|), hₙ(|x|) is constructed as

$${h}_{n} ( \vert x \vert ) = {\sum }_{k = 1}^{K} {e}^{- {γ}_{k} {‖ x ( n ) - {μ}_{k} ‖}^{2}} \qquad ( 6 )$$

where K is the number of RBF used, γₖ is a parameter setting the width of each RBF, x(n) is a vector of current and previous M samples composed as x(n)=[x(n), x(n−1), . . . , x(n−M))]^{T} and μₖ are the centroids of the RBFs found using—for example—K-means method. For more elaboration of RBF construction and usage for DPD, see M. Isaksson, D. Wisell and D. Ronnow, “Wide-band dynamic modeling of power amplifiers using radial-basis function neural networks,” in IEEE Transactions on Microwave Theory and Techniques, vol. 53, no. 11, pp. 3422-3428 November 2005.

The model parameters vector

$${w}_{amp}^{l}$$

in the DPD model may then be estimated using least square regression as:

$${w}_{amp}^{l} = {( {H ( \vert x \vert )}^{T} H ( \vert x \vert ) )}^{- 1} {H ( \vert x \vert )}^{T} \vert {u}_{l} \vert \qquad ( 7 )$$

where the desired amplitudes of the DPD output signal in the OoB region of interest |uₗ| may be learnt beforehand using a conventional DPD learning architectures.

The method of FIG. 1 further comprises, in step 106, replacing the out-of-band component, x_{OoB}, of the first signal with a third signal, z, derived from the amplitudes of the second signal, |ûₗ|, to obtain the pre-distorted signal, x_{pre-d}. The third signal, z, consists of the one or more second frequency bands. In other words, the third signal, z, consists of the same frequency bands as the OoB component of the first signal, x_{OoB} (e.g., the OoB region of interest, l).

It will therefore be appreciated that the method of FIG. 1 utilises the amplitudes of the first input signal to model desired amplitudes for the OoB component of the DPD output signal. The method of FIG. 1 may then effectively replace the OoB components of the input signal with these desired amplitudes for the OB component of the DPD output signal in order to provide the output signal of the DPD (e.g. The pre-distorted signal, x_{pre-d}.

According to some embodiments, the third signal, z, is derived from the amplitudes of the second signal, |ûₗ|, by performing one or more second processing steps. For example, the one or more second processing steps may be any one or more of the second processing steps described later with reference to FIG. 2.

As noted above, the objective of OoB amplitude-only DPD is to minimise the OoB energy, which depends solely on amplitudes of the OoB region of interest, l (i.e., of the one or more second frequency bands). However, if the OoB component of the first signal, x_{OoB}, is replaced with amplitudes only (i.e., with zero phase), then the resulting pre-distorted signal may cause a DC offset which appears in the output of the PA as a single frequency component at the center of the OoB region of interest, l. This single frequency component may significantly harm a single physical resource block (PRB). Thus, in some embodiments, the one or more second processing steps (performed to derive the third signal, z, from the amplitudes of the second signal, |ûₗ|) comprises adding phases to the amplitudes of the second signal |uₗ| (e.g., by multiplying |ûₗ| by e^{jφ} where φ are the phases to generate ûₗ) to eliminate the DC offset in the baseband representation of the OoB region of interest, and thus the single frequency component at the center of the OoB region of interest, l.

In some of these embodiments, the phases, φ, are the phases of the out-of-band component of the first signal, x_{OoB}. Thus, the one or more second processing steps may comprise adding phases of the out-of-band component of the first signal, x_{OoB}, such that the third signal, z, has the same phases as the out-of-band component of the first signal, x_{OoB}. In other words, the amplitudes of x_{OoB} are replaced in step 106, but the phases of x_{OoB} are effectively maintained.

In alternative embodiments, the single frequency component is eliminated by randomising the phases of ûₗ. Thus, the added phases, φ, are random phases). The first signal, x, has very small amplitudes in the OoB region of interest (due to imperfections in orthogonal frequency-division multiplexing (OFDM) signal generation and the residual effects of channel filtering) compared to its in-band region amplitudes. As such, the phases in the OoB region of interest can be assumed to hold no information, and replacing the OoB phases of x with random phases has the same impact of eliminating DC offset in the baseband representation of the OoB region of interest.

The actual phase values are irrelevant because they are added in an OoB region of interest, and therefore the reduced energy by amplitude only DPD is not affected. Accordingly, in these embodiments, the step of adding the phases may be expressed as:

$${\hat{u}}_{l}^{′} = \vert {\hat{u}}_{l}^{′} \vert {e}^{i ϕ} \qquad ( 5 )$$

$$where$$

$$ϕ = \{ \begin{matrix}∠ {x}_{l} \\ rand ( - π , π )\end{matrix} \qquad ( 6 )$$

Here, |û′ₗ| are either the amplitudes of the second signal, or the amplitudes of a signal obtained by performing one or more of the one or more second processing steps (performed to derive the third signal, z, from the amplitudes of second signal, |ûₗ|).

FIG. 2 illustrates a DPD system 200 according to some embodiments. The DPD system 200 is for performing amplitude-only OoB DPD on a first signal, x. For example, the DPD system 200 may be for performing DPD on a first signal, x, in accordance with some embodiments of the method of FIG. 1. The solid lines of FIG. 2 illustrate an apparatus for performing DPD using a DPD model and a set of DPD actuator components comprised in the DPD system 200. An example feedback path for learning the DPD model is depicted in FIG. 2 by dashed lines.

As described with respect to FIG. 1, the first signal comprises an in-band component, x_{iB}, consisting of one or more first frequency bands and an out-of-band component, x_{OoB}, consisting of one or more second frequency bands. The in-band component may comprise frequencies used for carrying data, whilst the out-of-band component may comprise unused frequencies. For example, the first signal may be a single-carrier signal and the out-of-band component may comprise unused subcarrier frequencies of the single-carrier signal.

To perform DPD on the first signal, the first signal is passed through three parallel paths, which are labelled in FIG. 2 as path 1, path 2 and path 3. Path 2 further comprises two arms, referred to as path 2.1 and path 2.2 respectively. Paths 1, 2 and 3 are parallel paths in that the signals may be considered to be processed in all three paths concurrently. All three paths effectively terminate at a replacement module 260. The output of the replacement module 260 comprises the pre-distorted signal, x_{pre-d}. The replacement module 260 may be considered to perform step 106 of FIG. 1 as will be described in more detail below.

On path 1, the first signal, x, is passed to the replacement module 260. However, in some examples, the first signal, x, may first be passed through a first delay module 211 on path 1 configured to temporally align the first signal arriving at the replacement module 260 with the signals arriving at the replacement module 260 on paths 2 and 3. The delay period of the first delay module 211 may be determined by the greater of: the time taken for the first signal to be processed by path 2.1, the time taken for the first signal to be processed by path 3 and/or the longest group delay of the filters in paths 2 and 3 (221 and 235). The first signal may be otherwise unchanged by path 1.

On path 2.1, the first signal may be passed to a filter 221 which removes the in-band component of the first signal and transmits the OoB component, x_{OoB}, (i.e., the filter passes the one or more second frequency bands) to the replacement module 260. Thus, path 2.1 is used to obtain the part of the first signal in the OoB region of interest (i.e., consisting of the one or more second frequency bands), x_{OoB}. Path 2.1 may also comprise a second delay module 222 configured to temporally align the output signal of path 2.1 with the output signal of paths 1 and 3.

Path 2.2 provides the phases to be included in the third signal z. As described above with reference to FIG. 1, two options are available for adding phases to the third signal z. In some examples, in path 2.2 the first signal is first passed to the filter 221 which removes the in-band component of the first signal and transmits the OoB component, x_{OoB}, (i.e., the filter passes the one or more second frequency bands) to a phase extractor 243. The phase extractor 243 extracts the phases φ from the signal x_{OoB}.

The phase module 243 then provides these phases to an exponent module 244. The exponent module outputs exp(jφ) and provides this to a phase module 238 in path 3 via a third delay module 242. The third delay module 242 is configured to temporally align the output signal of path 2.2 with the signal of path 3 at the phase module 238. The function of the phase module 238 will be described in more detail below.

In other examples the phases ¢ are provided to the exponent module 244 by a random phase generator 245.

On path 3, the first signal may be subject to one or more first processing steps (e.g. frequency shifting and down-sampling), which were discussed with reference to FIG. 1 and are discussed in more detail below. It will be appreciated that the one or more first processing steps may be performed in any suitable order.

Amplitudes of the first signal, |x|, are then obtained at a first amplitude module 233 (here the first signal may be the first signal in its initial form or the first signal after having been subjected to the one or more first processing steps). The first amplitude module 233 may therefore be considered to perform step 102 of FIG. 1. The amplitudes of the first signal are then passed to a DPD module 234 which applies a DPD model to the amplitudes of the first signal to obtain amplitudes of a second signal, |ûₗ|. The DPD module 234 may therefore be considered to perform step 104 of FIG. 1. The amplitudes of the second signal may then be subject to one or more second processing steps to derive a third signal, z which is passed to the replacement module 260. The one or more second processing steps were discussed with reference to FIG. 1 and are discussed in more detail below. It will be appreciated that the one or more second processing steps may be performed in any suitable order.

The first signal, x, obtained on path 1; the OoB component, x_{OoB}, obtained on path 2.1; and the third signal, z, obtained on path 3 are then passed to a replacement module 260. It will be appreciated that the first and second delay modules may be configured such that the first signal, x, obtained on path 1; the OoB component, x_{OoB}, obtained on path 2.1; and the third signal, z, obtained on path 3 are time aligned at the replacement module 260.

At the replacement module, the first signal, x, provided by path 1 is modified by replacing its OoB component, x_{OoB}, with the third signal, z, provided by path 3 to obtain a pre-distorted signal, x_{pre-d}. In other words, the replacement module 260 may be considered to perform step 106 of FIG. 1. To achieve this replacement, the replacement module modifies the first signal, x, provided by path 1 by:
subtracting the OoB component, x_{OoB}, provided by path 2.1; and
adding the third signal, z, provided by path 3.

The pre-distorted signal, x_{pre-d} may then be passed to the power amplifier 270.

The one or more first processing steps on path 3 may comprise frequency shifting. Thus, FIG. 2 depicts a first frequency shifter 231 on path 3. The first frequency shifter 231 is configured to shift the first signal (in its initial form or after being subjected to any of the other one or more first processing steps) so that the first signal is centered around the central frequency of the in-band component. In other words, the central frequency of the in-band component is set to “zero” frequency. The first frequency shifter 231 may take as input: (i) the signal to be frequency shifted (for example, the signal x before or after any of the one or more first processing steps), and (ii) the amount by which the signal is to be frequency shifted. Thus, the first frequency shifter 231 may receive an indication of the centre frequency f_{xiB} of x_{iB}. In some cases frequency shifter 231 is configured to shift the frequencies up by whatever frequency is received as an input, and therefore the frequency shifter 231 receives an input of −f_{xiB} in order to cause the frequency to shift down. However, the amount by which the signal is to be frequency shifted may, in some embodiments, be received by the first frequency shifter 231 as an amplitude only, and the direction of the frequency shift may be determined by some other logic (e.g. within the frequency shifter).

The one or more first processing steps on path 3 may comprise down sampling. Thus, FIG. 2 depicts a first down sampler 232 on path 3. The first down sampler 232 is configured to down-sample the first signal (either the first signal in its initial form or the first signal after being subjected to any of the other one or more first processing steps) to a sample rate equal to or greater than the greater of: (i) a minimum sampling rate required to reconstruct the out-of-band component, x_{OoB}, of the first signal, and (ii) a minimum sampling rate required to reconstruct the in-band component, x_{iB}, of the first signal. The minimum sampling rate required to reconstruct a signal component is equivalent to the bandwidth of that component. Therefore, in some embodiments, the first down-sampler 232 down-samples the signal to a sampling rate equal to or greater than the greater of: (i) the bandwidth of the out-of-band component, x_{OoB}, of the first signal, and (ii) the bandwidth of the in-band component, x_{iB}, of the first signal.

Thus, if the bandwidth of x_{OoB} is narrower than the bandwidth of x_{iB}, the first down-sampler 232 down-samples the first signal to a sampling rate equal to the bandwidth of x_{iB}. Otherwise, the first down-sampler 232 down-samples the first signal to a sampling rate equal to the bandwidth of x_{OoB}.

FIG. 3 illustrates the effect of the first down-sampler 232 for different types of signals, where each signal illustrated in FIG. 3 corresponds to a possible first signal, x, according to some embodiments. The shaded region of the signal is the out-of-band region of interest, i.e., the out-of-band component, x_{OoB}, consisting of one or more second frequency bands.

In scenario 1a, the first signal is a single carrier signal. The bandwidth of x_{OoB} is narrower than the bandwidth of x_{iB}, and therefore the down-sampler down samples the input signal to a sampling rate equal to the bandwidth of x_{iB}.

In scenario 1b, the input signal is a dual carrier signal. The bandwidth of x_{OoB} (the intercarrier signal) is narrower than the bandwidth of x_{iB}, and therefore the down-sampler again down samples the input signal a sampling rate equal to the bandwidth of x_{iB}.

In scenario 2a, the input signal is a single carrier signal (as in scenario 1a), however, in this example, the bandwidth of x_{OoB} is greater than the bandwidth of x_{iB}, and therefore the down-sampler down samples the input signal to a sampling rate equal to the bandwidth of x_{OoB}.

Thus, the first down sampler 232 depicted in FIG. 2 aims to down-sample the first signal to a sample rate equal to or greater than a minimum sampling rate required to reconstruct the out-of-band component, x_{OoB}, of the first signal, subject to the requirement that a sampling rate lower than the bandwidth of x_{iB} is not allowed, even if the bandwidth of x_{OoB} is narrower than the bandwidth of x_{iB}.

In some examples, the one or more second processing steps may comprise low pass filtering. The low pass filtering may be performed by the low pass filter 235 depicted in FIG. 2. The low pass filter 235 is configured to transmit only the OoB region of interest, i.e., the one or more second frequency bands.

In some examples, the one or more second processing steps comprises low pass filtering if the bandwidth of x_{OoB} is narrower than the bandwidth of x_{iB} (and thus the first signal is re-sampled at a sample rate equal to a minimum sampling rate required to reconstruct the in-band component, x_{iB}).

If the OoB region of interest is not narrower than the bandwidth of x_{iB}, then the low pass filter 235 may not be required and may be bypassed.

The one or more second processing steps may comprise up sampling. The up sampling may be performed by the up sampler 236 depicted in FIG. 2. The up sampling may comprise re-sampling such that the third signal, z, has a sample rate equal to a sample rate of the first signal, x (prior to the down sampling performed by the down sampler 232). It will be appreciated that the up sampler 236 may be considered to effectively reverse the effects of the down sampler 232.

The one or more second processing steps may comprise frequency shifting. The frequency shifting may be performed by the second frequency shifter 237 depicted in FIG. 2. The frequency shifting comprises frequency shifting such that the third signal, z, consists of the one or more second frequency bands. The second frequency shifter 237 may take as input: (i) the signal to be frequency shifted, and (ii) the amount by which the signal is to be frequency shifted. Thus, the second frequency shifter 237 may receive the centre frequency of x_{OoB}, which is labelled f_{xOoB} in FIG. 2. As described above for frequency shifter 231, the frequency shifter 237 may be configured to shift the frequency of the input (i) up by whatever is indicted in input (ii). However, the amount by which the signal is to be frequency shifted may, in some embodiments, be received by the second frequency shifter 237 as an amplitude only, and the direction of the frequency shift may be determined by some other logic (e.g. within the frequency shifter).

The one or more second processing steps may comprise adding phases to the signal in path 3. The phases may be added by the phase module 238. As described with respect to FIG. 1, the phases may be, for example, random phases. Alternatively, the phases may be the phases of the out-of-band component, x_{OoB}, of the first signal, such that the third signal, z has phases of the out-of-band component of the first signal. The phases of the out-of-band component, x_{OoB}, of the first signal may be obtained from the first signal transmitted by path 2.2, as described above.

The phase module 238 may multiply its two inputs to add the exponential phase component exp (j φ) to the signal in path 3.

It will therefore be appreciated that the replacement module receives three inputs: the first signal x from path 1, the OoB component of the first signal x_{OoB} from path 2.1 and the third signal z from path 3. The replacement module 260 then performs the following in order to output x_{pre-d}.

$${x}_{pre - d} = x - {x}_{OoB} + z$$

The signal x_{pre-d} is then passed to the power amplifier 270. Although not shown in FIG. 2, it will be understood by the skilled person that a digital-to-analogue converter (DAC) may be used to convert the signal x_{pre-d} to analogue before passing the signal x_{pre-d} to the power amplifier 270.

As described with reference to FIG. 1, the DPD model implemented by the DPD module 234 may be learnt using a learning architecture 251. An example feedback path for learning the DPD model is depicted in FIG. 2 using dashed lines. It will be appreciated that this feedback path may be implemented offline (e.g. prior to the deployment of the DPD system) or may only be implemented when required, for example, if it is expected that a change in the PA 270 may have caused a change to its non-linear response.

Learning the DPD model may comprise obtaining an output signal y derived from an output of the power amplifier. The output of the power amplifier may, for example, be obtained by inputting a first signal, x, directly into the power amplifier. Alternatively, the output of the power amplifier may be obtained by the method described with respect to FIG. 1 with a pre-configured or test DPD model.

Learning the DPD model may further comprise inputting the output signal, y, and the first signal, x, into the learning architecture 251 to obtain a pre-distorted learnt signal,

$${x}_{pre - d}^{L} .$$

The learning architecture 251 may output the pre-distorted learnt signal

$${x}_{pre - d}^{L} .$$

It will be appreciated that the learning architecture 251 may perform conventional DPD learning methods utilising for example an ILA, a DLA or ILC. The learning architecture 251 may receive the first signal, x, as an input and may strive to learn the pre-distorted learnt signal

$${x}_{pre - d}^{L}$$

that, if input into the power amplifier, would bring the output signal y equal to a linearly scaled first signal x. It will be appreciated that the learning architecture 251 may work across both the in-band and out-of-band regions.

Learning the DPD model may further comprise determining the DPD model based on amplitudes of components of the pre-distorted learnt signal consisting of the one or more second frequency bands (e.g. the OoB region of interest). The amplitudes of components of the pre-distorted learnt signal consisting of the one or more second frequency bands may be obtained via one or more third processing steps. It will be appreciated that the one or more third processing steps may be performed in any suitable order.

For example, the one or more third processing steps may comprise filtering the predistorted learnt signal

$${x}_{pre - d}^{L}$$

to obtain its components within the OB region of interest (i.e., consisting of the one or more second frequency bands). The filtering may be performed by filter 252 depicted in FIG. 2. The filter 252 may be a low pass filter.

The one or more third processing steps may further comprise frequency shifting. The frequency shifting may be performed by a third frequency shifter 253. For example, the third frequency shifter 253 may be configured to centre the predistorted learnt signal around a centre frequency of the OoB region of interest. In other words, the centre frequency of the OoB region of interest is made the “zero” frequency of the predistorted learnt signal. The third frequency shifter 253 may take as input: (i) the signal to be frequency shifted

$$( {x}_{pre - d}^{L}$$

before or after any of the one or more third processing steps), and (ii) the amount by which the signal is to be frequency shifted. Thus, the third frequency shifter 253 may receive an indication of the centre frequency f_{xOoB} Of x_{OoB}. In some cases, frequency shifter 231 is configured to shift the frequencies up by whatever frequency is received as an input, and therefore the frequency shifter 231 receives an input of −f_{xOoB} in order to cause the frequency to shift down. However, the amount by which the signal is to be frequency shifted may, in some embodiments, be received by the third frequency shifter 253 as an amplitude only, and the direction of the frequency shift may be determined by some other logic (e.g. within the frequency shifter).

The one or more third processing steps may further comprise down sampling. For example, a second down-sampler 254 may be configured to down sample the OoB predistorted signal to a sample rate equal to or greater than the greater of: (i) a minimum sampling rate required to reconstruct the out-of-band component of the predistorted signal, and (ii) a minimum sampling rate required to reconstruct the in-band component of the predistorted signal. As noted above, the minimum sampling rate required to reconstruct a signal component is equivalent to the bandwidth of that component. Therefore, in some embodiments, the second down-sampler 254 down samples the signal to a sampling rate equal to the greater of: (i) the bandwidth of the out-of-band component of the predistorted signal, and (ii) the bandwidth of the in-band component of the predistorted signal. This may correspond to the rate of the amplitude-only DPD.

The one or more third processing steps may further comprise obtaining amplitudes. For example, a second amplitude module 255 may be configured to obtain amplitudes of the components of the pre-distorted learnt signal,

$${x}_{pre - d}^{L} .$$

The output of the steps of filtering and, in some examples, frequency shifting and down sampling, may be referred to as uₗ. The one or more third processing steps may comprise obtaining the amplitudes of uₗ. The amplitudes of uₗ may be considered to represent the desired output of amplitude-only DPD model and are therefore passed to the amplitude-only DPD model 234.

The DPD model of the method described with reference to FIGS. 1 and 2 may be updated. For example, the DPD model may be periodically updated. Alternatively, the DPD model may be updated in response to an update request. For example, the update request may be based on traffic variation, power control, and/or changes to relevant infrastructure, hardware and/or software.

Another use case for amplitude-only DPD is for electrically large antenna arrays when beam domain DPD that corrects for EVM in the user beam is used to have a better scaling of complexity with traffic instead of number of branches. However, due to PA non-linearity out of band emission exists in more directions than user beams directions (the number of directions of IMs depends on the number of beams), and beam domain DPD cannot combat such out of band off-beam distortion.

A complementary solution to beam domain DPD could be a per-branch simplified DPD that corrects for out-of-band only, and the techniques of the present disclosure can be used for this purpose. Having in-band only beam domain DPD is of a great advantage as beam domain DPD can run at a lower rate. In fact, such setup makes beam domain DPD more attractive from a complexity point of view since DPD is the block that runs at the highest rate in the chain and all following blocks needs to run at that rate.

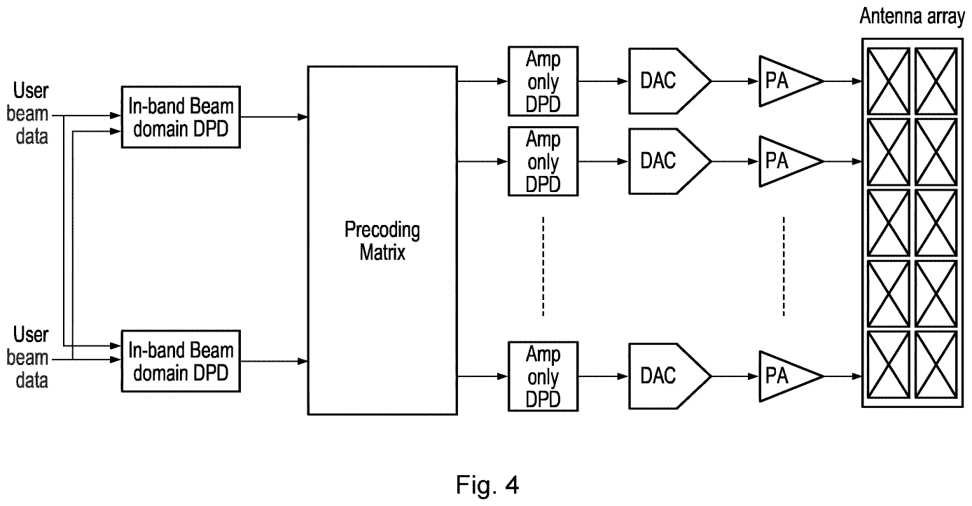

FIG. 4 depicts a block diagram for an AAS with in-band beam domain DPD and amplitude only out-of-band per-branch DPD. In this figure, the input to amplitude only DPD for each branch is an output of a pre-coding matrix. The precoding matrix in this example receives it is input from pre-distorted signals in the beam domain.

FIG. 5 illustrates an apparatus 500 comprising processing circuitry (or logic) 501. The processing circuitry 501 controls the operation of the apparatus 500 and can implement the method described herein in relation to the apparatus 500. The processing circuitry 501 can comprise one or more processors, processing units, multi-core processors or modules that are configured or programmed to control the apparatus 500 in the manner described herein. In particular implementations, the processing circuitry 501 can comprise a plurality of software and/or hardware modules that are each configured to perform, or are for performing, individual or multiple steps of the method described herein in relation to the apparatus 500. It will be appreciated that the apparatus 500 may comprise one or more virtual machines running different software and/or processes. The apparatus 500 may therefore comprise, or be implemented in or as one or more servers, switches and/or storage devices and/or may comprise cloud computing infrastructure that runs the software and/or processes.

Briefly, the processing circuitry 501 of the apparatus 500 is configured to perform the method as described with reference to FIG. 1, and/or the method described with reference to FIG. 2.

In some embodiments, the apparatus 500 may optionally comprise a communications interface 502. The communications interface 502 of the apparatus 500 can be for use in communicating with other nodes, such as other virtual nodes. For example, the communications interface 502 of the apparatus 500 can be configured to transmit to and/or receive from other nodes requests, resources, information, data, signals, or similar. The processing circuitry 501 of apparatus 500 may be configured to control the communications interface 502 of the apparatus 500 to transmit to and/or receive from other nodes requests, resources, information, data, signals, or similar. The communications interface 502 can use any suitable communication technology.

Optionally, the apparatus 500 may comprise a memory 503. In some embodiments, the memory 503 of the apparatus 500 can be configured to store program code that can be executed by the processing circuitry 501 of the apparatus 500 to perform the method described herein in relation to the apparatus 500. Alternatively or in addition, the memory 503 of the apparatus 500, can be configured to store any requests, resources, information, data, signals, or similar that are described herein. The processing circuitry 501 of the apparatus 500 may be configured to control the memory 503 of the apparatus 500 to store any requests, resources, information, data, signals, or similar that are described herein. The apparatus 500 may be configured operate in the manner described herein in respect of an apparatus.

FIG. 6 is a block diagram illustrating an apparatus 600 according to some embodiments. The apparatus 600 can perform digital predistortion, DPD, on a first signal, x, to generate a pre-distorted signal, x_{pre-d}, for driving a power amplifier. The first signal comprises an in-band component, x_{iB}, consisting of one or more first frequency bands and an out-of-band component, x_{OoB}, consisting of one or more second frequency bands. It will be appreciated that the apparatus 600 may be configured to perform the method of FIG. 1. The apparatus 600 may also implement any of the modules or blocks illustrated in FIG. 2.

The apparatus 600 comprises an amplitude module 601 configured to obtain amplitudes, |x|, of the first signal. The amplitude module 601 may, for example, be the first amplitude module 233 of FIG. 2.

The apparatus 600 comprises a DPD module 602 configured to perform DPD by applying a DPD model to the amplitudes of the first signal to obtain amplitudes of a second signal, |ûₗ|. The DPD module 602 may, for example, be the DPD module 234 of FIG. 2.

The apparatus 600 further comprises a replacement module 603 configured to replace the out-of-band component, x_{OoB}, of the first signal with a third signal, z, derived from the amplitudes of the second signal, |ûₗ|, to obtain the pre-distorted signal, x_{pre-d} wherein the third signal, z, consists of the one or more second frequency bands. The replacement module 603 may, for example, be the replacement module 260 of FIG. 2.

The dashed lines of FIG. 6 illustrate a transmission direction of the first signal through the apparatus 600. It is to be understood that the first signal may pass through further modules (not shown in FIG. 6) between each of the modules depicted in FIG. 6.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1.-52. (canceled)

53. A method of performing digital predistortion (DPD) on a first signal, x, to generate a pre-distorted signal, x_{pre-d}, for driving a power amplifier, the method comprising:
obtaining amplitudes, |x|, of the first signal, wherein the first signal comprises:
an in-band component, xiB, consisting of one or more first frequency bands, and
an out-of-band component, x_{OoB}, consisting of one or more second frequency bands;
performing DPD by applying a DPD model to the amplitudes of the first signal to obtain amplitudes of a second signal, |ûₗ|; and
replacing the out-of-band component, x_{OoB}, of the first signal with a third signal, z, derived from the amplitudes of the second signal, |ûₗ|, to obtain the pre-distorted signal, x_{pre-d}, wherein the third signal, z, consists of the one or more second frequency bands.

54. The method of claim 53, further comprising, prior to obtaining the amplitudes of the first signal, performing one or more first processing steps on the first signal.

55. The method of claim 54, wherein the one or more first processing steps include one or more of the following:
down sampling the first signal to a sample rate equal to or greater than the greater of the following: (i) a minimum sampling rate required to reconstruct the out-of-band component, x_{OoB}, of the first signal, and (ii) a minimum sampling rate required to reconstruct the in-band component, xiB, of the first signal; and
frequency shifting the first signal such that the first signal is centered on a central frequency of the in-band component, xiB.

56. The method of claim 53 further comprising performing one or more second processing steps to derive the third signal, z, from the amplitudes of the second signal, |ûₗ|.

57. The method of claim 56, wherein the one or more second processing steps include one or more of the following:
low pass filtering and/or frequency shifting the amplitudes of the second signal, |ûₗ|, such that the third signal, z, consists of the one or more second frequency bands;
re-sampling the amplitudes of the second signal, |ûₗ|, such that the third signal, z, has a sample rate equal to a sample rate of the first signal;
adding phases to the amplitudes of the second signal, |ûₗ|, such that the third signal, z has one of the following: random phases, or phases of the out-of-band component of the first signal.

58. The method of claim 53 wherein the DPD model is pre-configured based on an output signal derived from an output of the power amplifier.

59. The method of claim 53, further comprising obtaining the DPD model using a learning architecture, including the following operations:
obtaining an output signal derived from an output of the power amplifier;
inputting the output signal and the first signal, x, into the learning architecture to obtain a learned pre-distorted signal,
$${x}_{pre - d}^{L} ;$$
and
determining the DPD model based on amplitudes of components of the learned pre-distorted signal,
$${x}_{pre - d}^{L} ,$$
consisting or the one or more second frequency bands.

60. The method of claim 59, wherein the learning architecture is one of the following:
an indirect learning architecture (ILA), a direct learning architecture (DLA), or an iterative learning control (ILC).

61. The method of claim 53, further comprising updating the DPD model in response to one of the following: a periodic update interval, an update request, a change in hardware and/or software of the power amplifier, or a change in traffic carried by the power amplifier.

62. The method of claim 53, wherein replacing the out-of-band component, x_{OoB}, of the first signal with the third signal, z, comprises:
filtering a first copy of the first signal to obtain the out-of-band component, x_{OoB}, of the first signal; and
performing the following operations on a second copy of the first signal: adding the third signal, z, and subtracting the out-of-band component, x_{OoB}, obtained from filtering the first copy.

63. The method of claim 62, further comprising, prior to performing the operations on the second copy, inputting the second copy and the out-of-band component, x_{OoB}, of the first copy and into respective delay units to time-align the second copy and the out-of-band component, x_{OoB}, of the first copy with the third signal, z.

64. The method of claim 53, wherein the first signal, x, is an output of a previous DPD operation.

65. An apparatus configured to perform digital predistortion (DPD) on a first signal, x, to generate a pre-distorted signal, x_{pre-d}, for driving a power amplifier, the apparatus comprising processing circuitry operably coupled to the power amplifier and configured to:
obtain amplitudes, |x|, of the first signal, wherein the first signal comprises:
an in-band component, xiB, consisting of one or more first frequency bands, and
an out-of-band component, x_{OoB}, consisting of one or more second frequency bands;
perform DPD by applying a DPD model to the amplitudes of the first signal to obtain amplitudes of a second signal, |ûₗ|; and
replace the out-of-band component, x_{OoB}, of the first signal with a third signal, z, derived from the amplitudes of the second signal, |ûₗ|, to obtain the pre-distorted signal, x_{pre-d}, wherein the third signal, z, consists of the one or more second frequency bands.

66. A network node configured for operation in a communication network, the network node comprising the apparatus of claim 65.

67. The network node of claim 65, wherein the network node is a base station.

68. Non-transitory, computer readable media having stored there on executable instructions that, when executed by processing circuitry of an apparatus configured to perform digital predistortion (DPD), configures the apparatus to perform the method of claim 53.
